(19) United States
(12) Patent Application Publication
(10) Pub. No.: US 2009/0065844 A1
(43) Pub. Date: Mar. 12, 2009

(54) NONVOLATILE SEMICONDUCTOR MEMORY DEVICE AND MANUFACTURING METHOD THEREOF

(76) Inventor: Toshihiko IINUMA, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/204,539

(22) Filed: Sep. 4, 2008

(30) Foreign Application Priority Data
Sep. 6, 2007 (JP) 2007-231630

(51) Int. Cl. H01L 21/28; H01L 29/788

(52) U.S. Cl. 257/316; 438/593; 257/E29.3; 257/E21.209

(57) ABSTRACT

A nonvolatile semiconductor memory device includes a plurality of nonvolatile memory cells each having a double-layered gate structure in which a floating gate and a control gate formed of a nickel silicide film are laminated, a first contact plug formed on a substrate contact portion of a surface of the semiconductor substrate, the first contact plug having a lower layer formed of a semiconductor film and an upper layer formed of a nickel silicide film, and second contact plugs formed on the control gates and first contact plug.

### CROSS-REFERENCE TO RELATED APPLICATIONS

This application is based upon and claims the benefit of priority from prior Japanese Patent Application No. 2007-231630, filed Sep. 6, 2007, the entire contents of which are incorporated herein by reference.

### BACKGROUND OF THE INVENTION

1. Field of the Invention

This invention relates to a nonvolatile semiconductor memory device including nonvolatile memory cells with double-layered gate structures each having a floating gate and control gate and more particularly to a nonvolatile semiconductor memory device in which the control gate is formed of a silicide material by means of a salicide process to reduce the parasitic resistance of a word line and a manufacturing method thereof.

2. Description of the Related Art

With the progress of miniaturization of a recent pattern, the word line width of a flash memory is rapidly reduced and it becomes yearly more difficult to sufficiently reduce the parasitic resistance of the word line. As a method for reducing the resistance of the word line, a method for laminating a tungsten silicide film or cobalt silicide film on a polysilicon film used as the word line is provided.

However, when the line width of the word line is made as small as 70 nm or less, it becomes difficult to sufficiently reduce the parasitic resistance even if a material of tungsten silicide, cobalt silicide or the like is used. Therefore, recently, it is required to form a nickel silicide film whose resistance can be easily reduced when it is formed with the small width by means of a salicide (self-aligned silicide) process.

When a metal portion is used in a control gate portion, it becomes necessary to greatly change the manufacturing process and serious difficulties will occur in practice if refractory metal is simply used instead of polysilicon. Therefore, usage of a so-called fully silicided (FUSI) process in which the control gate portion formed of polysilicon is modified into a silicide film by means of a salicide process is studied. As a representative material suitable for the FUSI process, a nickel silicide film is provided.

Thus, in order to advance the process of miniaturizing the flash memory in future, it is strongly required to apply the salicide process using nickel silicide. However, the nickel silicide film has a disadvantage that the heat resistance thereof is extremely lower than that of a tungsten silicide film or cobalt silicide film. If a word line formed of a nickel silicide film is used, there occurs a problem that it is extremely difficult to permit a thermal process at approximately 550° C. required when an ohmic contact portion is formed between a contact plug and an n-type diffusion layer.

In order to suppress contact leak in a substrate contact portion, a method for forming a contact plug formed of a laminated structure of polysilicon and cobalt silicide in the substrate contact portion is proposed (U.S. Pat. No. 6,720,579). However, with this structure, since cobalt silicide is used, the resistances of the contact plug and word line (thin lines of 40 nm or less) cannot be sufficiently reduced. Further, when an attempt is made to entirely modify the word lines into cobalt silicide films, voids may be made in the word lines to rapidly increase the resistances thereof.

### BRIEF SUMMARY OF THE INVENTION

According to one aspect of the present invention, there is provided a nonvolatile semiconductor memory device including a plurality of nonvolatile memory cells formed on a semiconductor substrate, each of the memory cells having a double-layered gate structure in which a floating gate and a control gate used as a word line are laminated and the control gate being formed of a nickel silicide film, a first contact plug formed on a to-be-contacted substrate contact portion of a surface of the semiconductor substrate, the first contact plug having a lower layer formed of a semiconductor film and an upper layer formed of a nickel silicide film, and second contact plugs formed on the control gates and first contact plug.

According to another aspect of the present invention, there is provided a manufacturing method of a nonvolatile semiconductor memory device including forming a plurality of nonvolatile memory cells which are formed on a semiconductor substrate and each have a double-layered gate structure in which a floating gate and a control gate used as a word line are laminated and in which the control gate is formed of a polysilicon film, forming a polysilicon film on a substrate contact portion to be brought into contact with a surface of the semiconductor substrate on which the nonvolatile memory cells are formed, siliciding the polysilicon film of the control gates from an upper surface side thereof, forming a nickel silicide film whose bottom portion is formed in direct contact with an electrode-electrode insulating film between the control gate and the floating gate, siliciding an upper portion of the polysilicon film of the substrate contact portion and forming a first contact plug having a laminated structure of the polysilicon film and nickel silicide film, and forming second contact plugs to connect the control gates and first contact plug to upper interconnection layers, respectively.

According to still another aspect of the present invention, there is provided a manufacturing method of a nonvolatile semiconductor memory device including forming a plurality of nonvolatile memory cells which are formed on a semiconductor substrate and each have a double-layered gate structure in which a floating gate and a control gate used as a word line are laminated and in which the control gate is formed of a polysilicon film, filling and forming a first interlayer insulating film in an area on the semiconductor substrate in which the double-layered gate structures are not formed, forming a contact opening in a portion of the first interlayer insulating film which lies on a substrate contact portion to be brought into contact with a surface of the semiconductor substrate, filling a polysilicon film into the contact opening of the first interlayer insulating film, siliciding the polysilicon film of the control gates from an upper surface side thereof, forming a nickel silicide film whose bottom portion is formed in direct contact with an electrode-electrode insulating film between the control gate and the floating gate, siliciding an upper portion of the polysilicon film of the substrate contact portion and forming a first contact plug having a laminated structure of the polysilicon film and nickel silicide film, forming a second interlayer insulating film to cover the memory cells, first interlayer insulating film and first contact plug, forming contact openings for connection with the control gates and a contact opening for connection with the first contact plug in the second interlayer insulating film, and filling and forming second contact plugs in the contact openings of the second interlayer insulating film.

### BRIEF DESCRIPTION OF THE SEVERAL VIEWS OF THE DRAWING

FIGS. 1A to 1F are cross-sectional views showing manufacturing steps of a nonvolatile semiconductor memory device according to a first embodiment of this invention.

FIG. 2 is a cross-sectional view taken along line A-A′ of FIG. 1A, for illustrating the manufacturing step of the nonvolatile semiconductor memory device according to the first embodiment.

FIG. 3 is a cross-sectional view taken along line B-B′ of FIG. 1F, for illustrating the manufacturing step of the nonvolatile semiconductor memory device according to the first embodiment.

FIGS. 4A to 4C are cross-sectional views showing manufacturing steps of a nonvolatile semiconductor memory device according to a second embodiment of this invention.

FIG. 5 is a cross-sectional view showing the schematic structure of a nonvolatile semiconductor memory device in which a word line is formed of cobalt silicide as a comparison example.

### DETAILED DESCRIPTION OF THE INVENTION

There will now be explained embodiments of the present invention in detail with reference to the accompanying drawings.

### First Embodiment

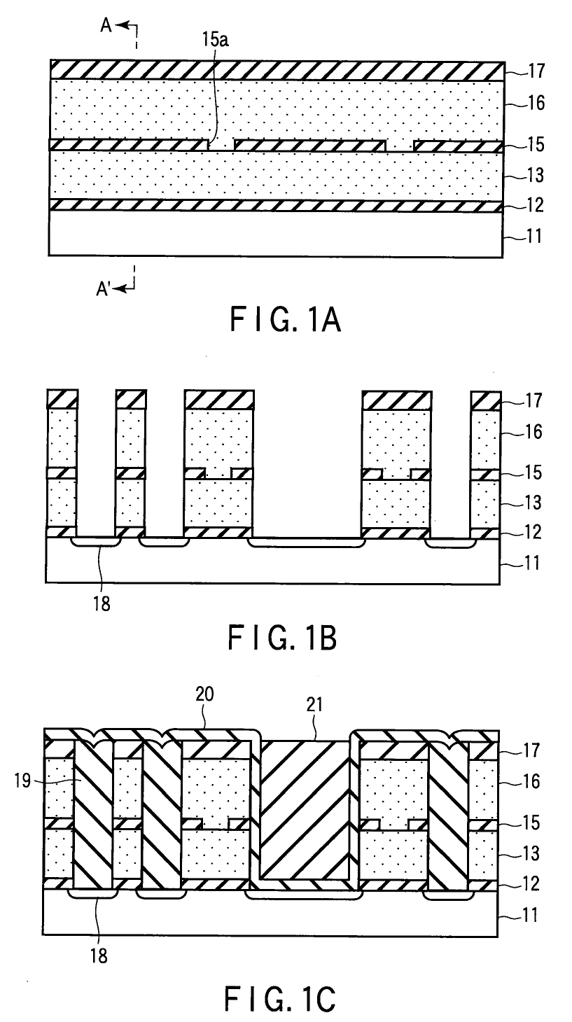

FIGS. 1A to 1F are cross-sectional views showing manufacturing steps of a nonvolatile semiconductor memory device according to a first embodiment of this invention. A memory cell in this embodiment has a double-layered gate structure in which a floating gate and control gate are laminated. Each NAND cell unit is configured by serially connecting a plurality of memory cells and providing select gates on both sides of the series-connected portion.

First, as shown in FIG. 1A, a tunnel insulating film 12 formed of a silicon oxide film and a floating gate 13 formed of phosphorus-doped polysilicon are sequentially deposited on a p-type silicon substrate 11. Then, after grooves are formed by etching the floating gate 13, tunnel insulating film 12 and silicon substrate 11 by means of an anisotropic etching method such as the RIE method, element isolation insulating films 14 are formed by filling silicon oxide films into the grooves.

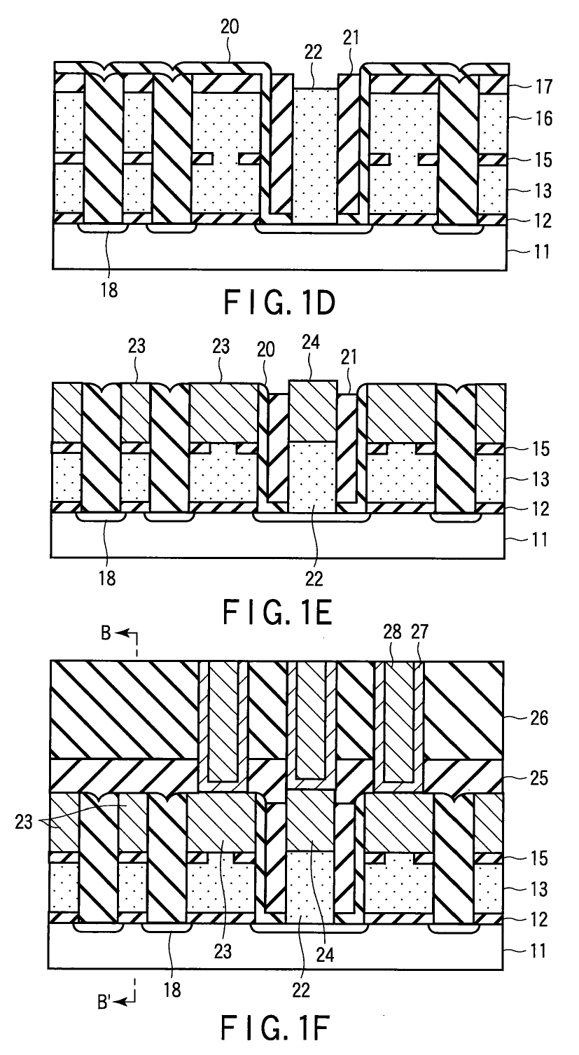

Next, an inter-poly insulating film (IPD) 15 formed of a silicon oxide film or silicon nitride film is formed on the entire surface and then portions 15a of the inter-poly insulating film 15 which lie on areas used as select gates are opened. After this, a phosphorus-doped polysilicon film 16 is deposited, the surface of the phosphorus-doped polysilicon film 16 is made flat by means of the CMP method or the like and then a silicon nitride film (cap layer) 17 is deposited on the polysilicon film 16. In this state, the cross section taken along line A-A′ of FIG. 1A is shown in FIG. 2.

Next, as shown in FIG. 1B, a groove formation process by the RIE method is performed in a direction perpendicular to the processing direction for the floating gates explained in FIG. 1A and FIG. 2. Word lines are formed by dividing the silicon nitride film 17, polysilicon film 16, inter-poly insulating film 15, floating gate 13 and tunnel insulating film 12 by formation of the grooves. Then, n-type diffusion layers (source and drain regions) 18 are formed by ion-implanting impurities such as phosphorus into the surface areas of the substrate 11 and performing the heat treatment.

Next, as shown in FIG. 1C, a silicon oxide film 19 is deposited by means of the CVD method and the silicon oxide film 19 is etched back by means of the RIE method or the like to expose the surfaces of the silicon nitride films 17. Further, a portion of the silicon oxide films 19 that lies on a substrate contact portion is removed. After this, a nitride film liner film 20 is formed on the entire surface, a silicon oxide film 21 such as a BPSG film is deposited by means of the CVD method and the silicon oxide film 21 is made flat by means of the CMP method.

Next, as shown in FIG. 1D, an opening portion is formed in the silicon oxide film 21 and silicon nitride film 20 by means of the RIE method or the like to form a first contact hole that reaches the surface of the n-type diffusion layer 18. Then, a natural oxide film lying on the surface of the n-type diffusion layer 18 is removed by a process using dilute hydrofluoric acid or the like and then a phosphorus-doped polysilicon film 22 is deposited. After this, a portion of the polysilicon film 22 that lies outside the first contact hole is etched back by a process such as the RIE method to fill the polysilicon film 22 only inside the first contact hole. Thus, a first contact plug is formed. Then, the natural oxide film that still lies between the polysilicon film 22 and the n-type diffusion layer 18 will be condensed by performing an RTA process at 1000° C. or higher and thus a complete ohmic contact portion can be formed.

Next, as shown in FIG. 1E, the silicon nitride film 20, silicon nitride film cap layer 17 and the surface layers of the silicon oxide films 19 are etched by means of the RIE method or the like to expose the surface portions of the polysilicon films 16. Then, the natural oxide films lying on the surfaces of the polysilicon films 16 of the word lines and the polysilicon film 22 of the first contact plug are removed by means of a chemical fluid process using dilute hydrofluoric acid or the like and a nickel film is deposited by sputtering. After this, by performing the heat treatment, the polysilicon films 16, 22 are silicided.

Next, an un-reacted nickel film is etched and removed by using a chemical fluid such as an aqueous Hydrochloric acid-Peroxide Mixture (HPM), an aqueous Sulphuric acid-Peroxide Mixture (SPM), an aqueous ammonium hydroxide and peroxide mixture (APM) or the like. At this time, the whole portions of the polysilicon films 16 used as control gates are silicided to form nickel silicide films 23 and thus a FUSI structure is attained. In the first contact plug, a nickel silicide film 24 is formed only on the upper portion of the polysilicon film 22.

In this case, in the substrate contact portion, a first contact plug with the laminated structure of polysilicon and nickel silicide is formed without siliciding the whole portion of the polysilicon film 22. Therefore, it becomes possible to prevent the nickel silicide film 24 and the surface of the substrate 11 from being directly brought into contact with each other and, for example, a problem that the surface of the substrate 11 is silicided will not occur.

Further, the word line basically has a FUSI structure in which the entire polysilicon portion is silicided, but there occurs no problem even if part of the polysilicon portion remains as it is without being silicided. Specifically, the polysilicon film 16 used as a control gate may be silicided from the upper surface side thereof and may be further silicided until the bottom portion thereof is directly brought into contact with the inter-poly insulating film 15 between the control gate and the floating gate. At this time, it is preferable to completely silicide the whole portion of the control gate, but there occurs almost no problem even if polysilicon partly remains in corner portions and if the amount thereof is small.

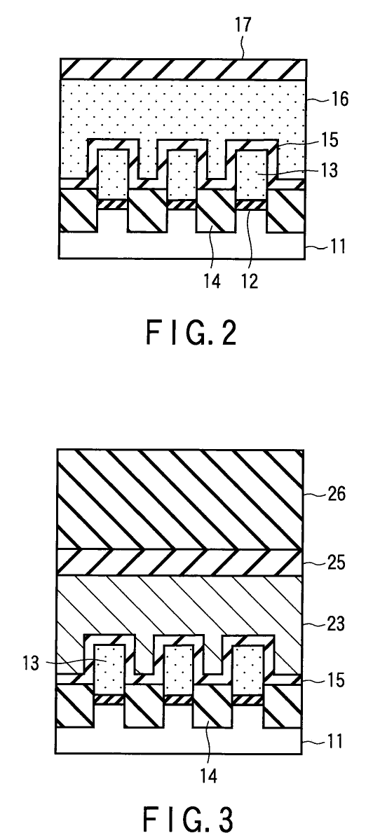

Next, as shown in FIG. 1F, a silicon nitride (liner) film 25 and silicon oxide film 26 are sequentially deposited on the entire surface and then the surface of the silicon oxide film 26 is made flat by means of the CMP method or the like. The cross section taken along line B-B′ of FIG. 1F in this state is shown in FIG. 3. Then, openings are formed in the silicon oxide film 26 and silicon nitride film 25 by means of the RIE method or the like to form second contact holes that reach the nickel silicide films 23 on the word lines and the nickel silicide film 24 on the first contact plug. After this, Ti/TiN laminated (barrier metal) films 27 are formed inside the second contact holes by sequentially depositing a titanium film and titanium nitride film by means of a method such as a sputtering method or the CVD method.

At this time, since the Ti/TiN laminated film 27 may be formed in ohmic contact not with the substrate silicon portion but only with the nickel silicide film, it is not always necessary to perform the heat treatment for forming TiSi₂. That is, only if a natural oxide film remaining on the surface layer of the nickel silicide film is removed by a preprocess when a Ti film is formed, an ohmic contact portion with sufficiently low resistance can be formed even in the heat treatment at approximately 400° C.

After this, tungsten films 28 used as second contact plugs are filled into the contact holes in which the Ti/TiN laminated films 27 are formed by means of the CVD method or the like. Then, the tungsten films 28 and Ti/TiN laminated films 27 lying outside the contact holes are removed by means of the CMP method or the like. In the cross section of FIG. 1F, second contact plugs on the word lines are not shown, but it is needless to say that second contact plugs are formed on the word lines in other cross sections.

Finally, a flash memory is completed by forming interconnection layers (not shown) connected to the tungsten films 28 filled in the contact holes.

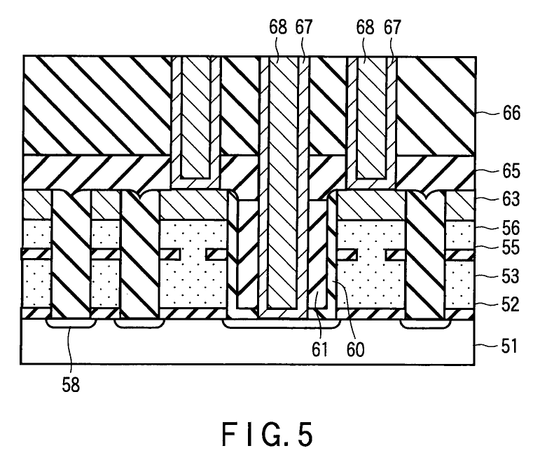

The schematic structure of the conventional flash memory in which cobalt silicide is used to form word lines in a salicide process is shown in FIG. 5 for comparison. A reference symbol 51 in FIG. 5 denotes a p-type silicon substrate, 52 tunnel insulating films, 53 floating gates, 55 inter-poly insulating films, 56 control gates (word lines) formed of phosphorus-doped polysilicon, 58 n-type diffusion layers (source and drain regions), 60 a silicon oxide film, 61 BPSG films, 63 cobalt silicide films, 65 a silicon nitride film, 66 a silicon oxide film, 67 Ti/TiN laminated (bimetal) films and 68 tungsten films.

In this device, the cobalt silicide films 63 are formed by performing a so-called salicide process in which a cobalt film is deposited on the polysilicon film formed as the control gates 56 and then the heat treatment is performed to make cobalt react with polysilicon. Further, tungsten is used for connections between the word lines and substrate contact portion and upper-layered interconnection layers.

Specifically, contact holes that reach the surfaces of the cobalt silicide films 63 and n-type diffusion layers 58 are formed in the silicon oxide film 66 and silicon nitride film 65 and then Ti/TiN laminated (bimetal) films 67 are deposited in the contact holes by means of a method such as a sputtering method or the CVD method. At this time, in order to form an ohmic contact portion between the barrier metal layer 67 and the surface layer of the n-type diffusion layer 58, it is necessary to perform the heat treatment at 550°C. or higher after the Ti film is formed and form the Ti film into a TiSi₂ form. The heat treatment for formation into the TiSi₂ form is performed by an annealing process at the TiN film formation time or after the TiN film formation. Then, tungsten films 68 are filled into the contact holes in which the barrier metal films 67 are formed by means of the CVD method or the like. After this, the tungsten films 68 and barrier metal films 67 that lie outside the contact holes are removed by means of the CMP method or the like and thus contact plugs are formed.

The structure shown in FIG. 5 is different from that of the present embodiment shown in FIG. 1F in that the word line is formed not with the FUSI structure of nickel silicide but with the laminated structure having the polysilicon film 56 and cobalt silicide film 63 and the substrate contact portion is a single-layered structure of the tungsten film 68.

Thus, according to the present embodiment, the word line is formed with the FUSI structure of nickel silicide and the substrate contact portion is formed with the laminated structure having polysilicon and nickel silicide. Therefore, even when a nickel silicide film with low heat resistance is provided as a FUSI film in the word line area, the temperature set in the heat treatment performed after the silicide film is formed can be set sufficiently low. Therefore, the parasitic resistance and the effective insulating film thickness of the IPD insulating film can be made small without causing a problem of condensation or the like of the nickel silicide film.

That is, even if the control gates are formed of the nickel silicide films 23 of low resistance by means of the salicide process in order to reduce the parasitic resistances of the word lines, the temperature in the heat treatment performed to form an ohmic contact portion by using the contact plug in the substrate contact portion can be set sufficiently low. Therefore, it becomes possible to form memory cells without causing condensation of the nickel silicide films 23.

Further, in the present embodiment, the upper portion of the first contact plug formed of phosphorus-doped polysilicon is silicided at the same time as the surface portions of the word lines, but it is possible to adjust an amount of the polysilicon region of the first contact plug to be left behind by adjusting an etch-back amount of the polysilicon film 22 in FIG. 1C.

### Second Embodiment

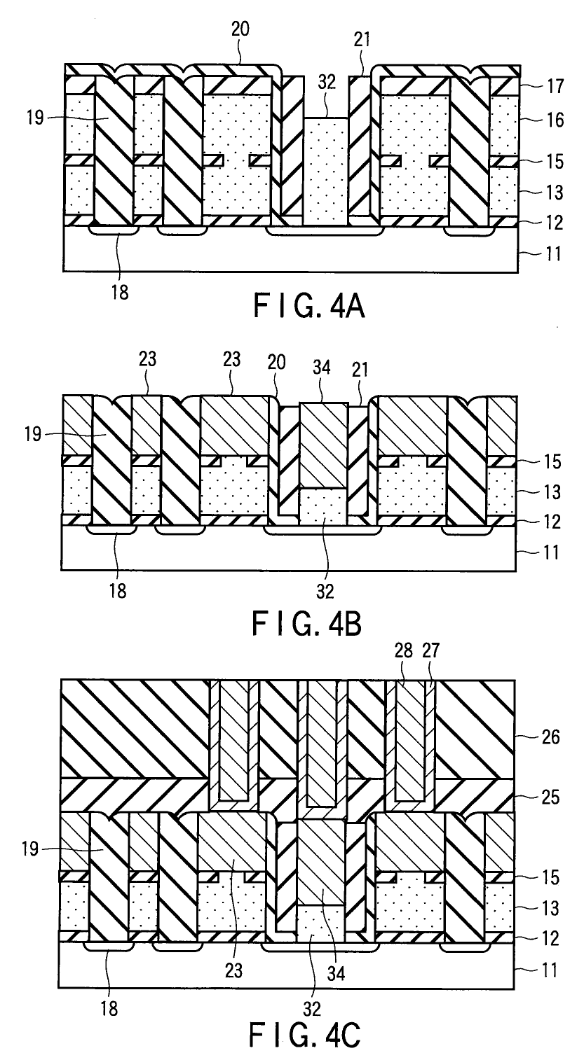

FIGS. 4A to 4C are cross-sectional views showing manufacturing steps of a nonvolatile semiconductor memory device according to a second embodiment of this invention. Portions that are the same as those of FIGS. 1A to 1F are denoted by the same reference symbols and the detailed explanation thereof is omitted.

The present embodiment is different from the first embodiment explained before in that a nickel silicide layer in a substrate contact portion is formed to reach a deeper position.

The process up to the steps shown in FIGS. 1A to 1C is the same as that of the first embodiment. In the present embodiment, after this, an opening is formed in a silicon oxide film 21 and silicon nitride film 20 by means of the RIE method or the like to form a first contact hole that reaches the surface of an n-type diffusion layer 18 as shown in FIG. 4A. Then, after a natural oxide film lying on the surface of the n-type diffusion layer 18 is removed by means of a method using dilute hydrofluoric acid, a phosphorus-doped polysilicon film 32 is deposited. After this, a portion of the polysilicon film that lies outside the first contact hole is etched back by a process such as the RIE method to fill the polysilicon film 32 inside the first contact hole and thus a first contact plug is formed.

At this time, an etch-back amount of the polysilicon film 32 is made larger than that in the first embodiment and the upper surface of the polysilicon film 32 is set at the lower position than the upper surfaces of polysilicon films 16 used as control gates. Then, a natural oxide film still lying between the polysilicon film 32 and the n-type diffusion layer 18 is condensed by performing the RTA process at 1000° C. or higher and thus a complete ohmic contact portion can be formed.

Next, as shown in FIG. 4B, the silicon nitride film 20, silicon nitride film cap layer 17 and the surface layers of the silicon oxide films 19 are etched by means of the RIE method or the like to expose the surface portions of the polysilicon films 16. Then, the natural oxide films lying on the surfaces of the polysilicon films 16 of the word lines and the surface of the polysilicon film 32 of the first contact plug are removed by means of a chemical fluid process using dilute hydrofluoric acid or the like and a nickel film is deposited by sputtering. After this, by performing heat treatment, the polysilicon films 16, 32 are formed into a nickel silicide film. After this, an un-reacted nickel film is etched and removed by using a chemical fluid such as HPM, SPM, APM or the like. At this time, the whole portions of the polysilicon films 16 used as control gates are silicided to form nickel silicide films 23 and attain a FUSI structure. In the first contact plug, a nickel silicide film 34 is formed only on the upper portion of the polysilicon film 32. In this case, the bottom portion of the nickel silicide film 34 is set lower than the bottom portion of the nickel silicide film 23 of the control gate.

After this, like the case of the first embodiment, as shown in FIG. 4C, a silicon nitride (liner) film 25 and silicon oxide film 26 are sequentially deposited on the entire surface and then openings are formed in the silicon oxide film 26 and silicon nitride film 25 to form second contact holes that reach the nickel silicide films 23 on the word lines and the nickel silicide film 34 on the upper portion of the first contact plug. After this, Ti/TiN laminated (barrier metal) films 27 are deposited on the inner portions of the second contact holes by means of a method such as a sputtering method or the CVD method.

At this time, since the Ti/TiN laminated film 27 may be formed in ohmic contact only with the nickel silicide film, it is not always necessary to perform the heat treatment for forming TiSi₂. That is, only if the natural oxide film remaining on the surface layer of the nickel silicide film is removed by a preprocess when a Ti film is formed, an ohmic contact portion with sufficiently low resistance can be formed even in the heat treatment at approximately 400° C.

After this, like the first embodiment, tungsten films 28 used as second contact plugs are filled into the contact holes in which the Ti/TiN laminated films 27 are formed. Finally, a flash memory is completed by forming interconnection layers (not shown) connected to the tungsten films 28 filled in the contact holes.

Thus, according to the present embodiment, since the word line is formed with the FUSI structure of nickel silicide and the substrate contact portion is formed with the laminated structure of polysilicon and nickel silicide, the same effect as that of the first embodiment can be attained. Further, since the nickel silicide film 34 in the substrate contact portion is formed to a position lower than the nickel silicide film 23 used as the control gate, the thickness of the polysilicon film 32 in the substrate contact portion can be made smaller. As a result, the series resistance of the substrate contact portion can be further reduced.

(Modification)

This invention is not limited to the above embodiments. In the embodiments, an example in which a plurality of nonvolatile memory cells are serially connected to configure a NAND cell unit is explained, but this invention is not limited to this case and can be applied to various types of nonvolatile semiconductor memory devices each having memory cells with the double-layered gate structure having a floating gate and control gate. Further, the lower layer of the first contact plug is not limited to the polysilicon film and any semiconductor material can be used if it contains silicon.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
a plurality of nonvolatile memory cells formed on a semiconductor substrate, each of the memory cells having a double-layered gate structure in which a floating gate and a control gate used as a word line are laminated and the control gate being formed of a nickel silicide film,
a first contact plug formed on a to-be-contacted substrate contact portion of a surface of the semiconductor substrate, the first contact plug having a lower layer formed of a semiconductor film and an upper layer formed of a nickel silicide film, and
second contact plugs formed on the control gates and first contact plug.

2. The device according to claim 1, wherein the second contact plug connects the control gate and first contact plug to upper interconnection layers, respectively.

3. The device according to claim 1, wherein the lower layer of the first contact plug is formed of a polysilicon film and the second contact plug is a film at least formed of tungsten.

4. The device according to claim 1, wherein a bottom portion of the nickel silicide film of the first contact plug is set lower in height from the surface of the substrate than a bottom portion of the control gate.

5. The device according to claim 1, wherein plural ones of the nonvolatile memory cells are serially connected to form a NAND cell unit.

6. The device according to claim 1, further comprising a first interlayer insulating film filled and formed on the semiconductor substrate to the same height as the double-layered gate structures of the nonvolatile memory cells, and a contact opening which is formed in the first interlayer insulating film to reach the substrate contact portion and in which the first contact plug is filled.

7. The device according to claim 6, further comprising a second interlayer insulating film formed to cover the nonvolatile memory cells, first interlayer insulating film and first contact plug, and contact openings formed in the second interlayer insulating film for connection with the control gates and for connection with the first contact plug, the second contact plugs being filled in the contact openings formed in the second interlayer insulating film.

8. A manufacturing method of a nonvolatile semiconductor memory device comprising:
forming a plurality of nonvolatile memory cells which are formed on a semiconductor substrate and each have a double-layered gate structure in which a floating gate and a control gate used as a word line are laminated and in which the control gate is formed of a polysilicon film,
forming a polysilicon film on a substrate contact portion to be brought into contact with a surface of the semiconductor substrate on which the nonvolatile memory cells are formed,
siliciding the polysilicon film of the control gates from an upper surface side thereof, forming a nickel silicide film whose bottom portion is formed in direct contact with an electrode-electrode insulating film between the control gate and the floating gate, siliciding an upper portion of the polysilicon film of the substrate contact portion and forming a first contact plug having a laminated structure of the polysilicon film and nickel silicide film, and
forming second contact plugs to connect the control gates and first contact plug to upper interconnection layers, respectively.

9. The method according to claim 8, further comprising setting an upper surface of the polysilicon film lower than an upper surface of the control gate when the polysilicon film is formed on the substrate contact portion, and setting a lower surface of the nickel silicide film lower than a lower surface of the control gate when an upper portion of the polysilicon film on the substrate contact portion is silicided to form the nickel silicide film.

10. The method according to claim 8, further comprising forming nickel films on the polysilicon film of the control gates and the polysilicon film on the substrate contact portion, respectively, after the polysilicon film is formed on the substrate contact portion to form the nickel silicide film, and then performing heat treatment to silicide a portion of the polysilicon film which is formed in contact with the nickel film.

11. The method according to claim 8, wherein a film at least formed of tungsten is used as the second contact plug.

12. A manufacturing method of a nonvolatile semiconductor memory device comprising:
forming a plurality of nonvolatile memory cells which are formed on a semiconductor substrate and each have a double-layered gate structure in which a floating gate and a control gate used as a word line are laminated and in which the control gate is formed of a polysilicon film,
filling and forming a first interlayer insulating film in an area on the semiconductor substrate in which the double-layered gate structures are not formed,
forming a contact opening in a portion of the first interlayer insulating film which lies on a substrate contact portion to be brought into contact with a surface of the semiconductor substrate,
filling a polysilicon film into the contact opening of the first interlayer insulating film,
siliciding the polysilicon film of the control gates from an upper surface side thereof, forming a nickel silicide film whose bottom portion is formed in direct contact with an electrode-electrode insulating film between the control gate and the floating gate, siliciding an upper portion of the polysilicon film of the substrate contact portion and forming a first contact plug having a laminated structure of the polysilicon film and nickel silicide film,
forming a second interlayer insulating film to cover the memory cells, first interlayer insulating film and first contact plug,
forming contact openings for connection with the control gates and a contact opening for connection with the first contact plug in the second interlayer insulating film, and
filling and forming second contact plugs in the contact openings of the second interlayer insulating film.

13. The method according to claim 12, further comprising sequentially laminating a tunnel insulating film, a polysilicon film used as the floating gates, the electrode-electrode insulating films and a polysilicon film used as the control gates to form the memory cells, and processing the above films into a gate pattern.

14. The method according to claim 12, further comprising setting an upper surface of the polysilicon film lower than an upper surface of the control gate when the polysilicon film is filled in the contact opening of the first interlayer insulating film, and setting a lower surface of the nickel silicide film lower than a lower surface of the control gate when an upper portion of the polysilicon film in the contact opening of the first interlayer insulating film is silicided to form the nickel silicide film.

15. The method according to claim 12, further comprising forming nickel films on the polysilicon film on the control gates and the polysilicon film on the substrate contact portion after the polysilicon film is filled in the contact opening of the first interlayer insulating film to form the nickel silicide film, and then performing heat treatment to silicide a portion of the polysilicon film which is formed in contact with the nickel film.

16. The method according to claim 12, wherein a film at least formed of tungsten is used as the second contact plug.
